(19) United States
(12) Patent Application Publication
(10) Pub. No.: US 2026/0228380 A1
(43) Pub. Date: Aug. 6, 2026

(54) AUTOMATED CELL SITE CONSTRUCTION PLAN GENERATION

(71) Applicant: DISH Wireless L.L.C., Englewood, CO (US)

(72) Inventors: Greg Ivey, Littleton, CO (US); Warren Newell Bloss, III, Castle Rock, CO (US); Salim Fermin, Castle Rock, CO (US)

(21) Appl. No.: 19/045,150

(22) Filed: Feb. 4, 2025

(51) Int. Cl. G06F 30/18; G06F 30/12; G06F 30/27

(52) U.S. Cl. CPC G06F 30/18; G06F 30/12; G06F 30/27

(57) ABSTRACT

Technologies for automatically generating cell site construction plans are described. One method receives, from a user device, user input about a cell site in the cellular network. The method receives, from the user device, a request to generate a cell site construction plan using the user input and a construction plan template. In response to the request, the method retrieves a copy of a construction plan template, identifies a subset of design elements from a set of pre-defined design elements. The method populates a plurality of frames of a cell site construction plan with the subset of design elements, and sends the cell site construction plan to the user device.

### BACKGROUND

Cell site construction plans are meticulously designed to ensure the optimal placement and functionality of cellular network infrastructure. The process involves a multidisciplinary approach that integrates engineering, regulatory compliance, project management, and environmental considerations.

The conventional process of generating cell site construction plans involves several manual steps that ensure optimal placement and functionality of cellular infrastructure. It begins with site selection, where demand analysis identifies areas with coverage gaps, capacity issues, or anticipated growth. Potential locations are assessed for technical feasibility, accessibility, and compliance with zoning laws, building codes, and environmental regulations. Following site selection, radio frequency (RF) planning uses advanced modeling tools to map signal coverage, minimize interference, allocate frequencies, and determine antenna configurations for maximum efficiency.

The site design phase involves structural engineering to ensure the physical structures, such as towers or rooftop setups, can withstand environmental conditions while accommodating equipment like antennas, radios, and cabling. Additionally, power and connectivity planning addresses electrical needs, backup power solutions, and backhaul connectivity through fiber, microwave, or satellite. Concurrently, regulatory and environmental compliance processes secure necessary permits and approvals, assess environmental impacts, and engage with local stakeholders to address concerns and gain community support.

Conventionally, Architecture and Engineering (A&E) firms are hired to generate construction drawings of a cell site construction plan. The A&E firms create the construction drawings using computer-aided design (CAD) programs or CAD tools. However, multiple A&E firms could be hired for different regions, resulting in disparate presentation of these drawings and other information in the cell site construction plan. The variety in the cell site construction plans make it difficult for downstream users, including the general and sub-contractors constructing the cell site. Conventional approaches to generating cell site construction plans are inefficient, as the A&E firms could spend 8-10 hours or even days to create the construction drawings for one cell site.

### BRIEF DESCRIPTION OF DRAWINGS

The present disclosure is illustrated by way of example, and not by way of limitation, in the figures of the accompanying drawings.

FIG. 1A is a block diagram of a system implementing a site plan generator tool for generating a cell site construction plan for a cell site in a cellular network system according to at least one embodiment.

FIG. 1B illustrates a tower with a typical 4G Remote Radio Head (RRH) and a tower with a typical 5G RU according to multiple embodiments.

FIG. 2 illustrates a site plan generator tool receiving user input and providing a cell site construction plan according to at least one embodiment.

FIG. 3 illustrates a process in which a site plan generator tool uses a site plan template and user input to generate a cell site construction plan for a cell site of a cellular network according to at least one embodiment.

FIG. 4A illustrates a process in which a site plan generator tool generates a dynamic block for a frame in a site plan template when generating a cell site construction plan for a cell site of a cellular network according to at least one embodiment.

FIG. 4B illustrates an example cell site construction plan with multiple dynamic blocks generated by a site plan generator tool according to at least one embodiment.

FIG. 5 illustrates a process in which a site plan generator tool analyzes user input and populates look-up tables with site information and equipment schedules according to at least one embodiment.

FIG. 6 illustrates a process in which the site plan generator tool generates a dynamic block using information in a LUT according to at least one embodiment.

FIG. 7 illustrates a process in which a site plan generator tool generates antenna specifications for a dynamic block using user input according to at least one embodiment.

FIG. 8 illustrates an example cell site construction plan 800 that is automatically generated by the site plan generator tool 104 based on user input 202 according to at least one embodiment.

FIG. 9 is a block diagram depicting a computing system on which at least a portion of the site plan generator tool may operate, according to at least one embodiment.

FIG. 10 is a flow chart of a method of automatically identifying a subset of design elements from a set of pre-defined design elements to populate frames of a cell site construction plan according to at least one embodiment.

FIG. 11 is a flow chart of a method of identifying a subset of design elements using an artificial intelligence (AI) or machine learning (ML) model to generate a cell site construction plan according to at least one embodiment.

### DETAILED DESCRIPTION

As described above, conventional approaches to cell site construction plans are inefficient and result in inconsistencies among cell site constructions plans. The inconsistencies can result in increased errors in the construction plans, as well as in the actual construction of the cell site. These approaches also do not allow for enhanced collaboration among A&E firms.

Aspects and embodiments of the present disclosure address these problems and others by providing a site plan generator tool and library of site plan templates (also referred to as construction drawing templates) and pre-defined design elements that facilitate automation of generating a cell site construction plan (also referred to herein as a site plan or a telecom site construction plan). A cell site construction plan is a detailed document (or documents) that provides a visual and technical representation of the proposed cellular infrastructure and its components. A cell site construction plan ensures that the infrastructure meets the technical and operational needs of the cellular network, the design complies with local, state, and federal regulations, and all stakeholders (engineers, contractors, regulators, and community members) understand the scope and details of the project. The cell site construction plan is an essential part of the planning and construction process, ensuring the cell site is designed efficiently, adheres to regulations, and meets operational requirements.

The site plan generator tool can be used to streamline the creation of construction drawings for cell sites (or telecom sites). The site plan generator tool can address inconsistencies and inefficiencies in construction drawings. The site plan generator tool includes standardized templates and libraries for A&E firms to use and following, which improves speed and consistency in creation and review. The templates include features like a title sheet with specific sections for city reviewers and general contractors, and general notes placed at the back to save time. Details such as antenna mounts and other components are standardized and can be easily inserted into drawings, minimizing production time and errors. The site plan generator tool can include an integrated artificial intelligence (AI) or machine learning (ML) models or systems (referred to herein as “integrated AI/ML system,” “AI/ML model,” or “AI/ML system”) that further reduces production time, achieving significant time savings in creating construction drawings. The site plan generator tool can be hosted on a server or cloud computing system, allowing dynamic changes and ensuring that all A&E firms use the most current versions. It should be noted that the site plan generator tool can allow for specific modifications to the templates by the A&E firms to accommodate jurisdiction-specific requirements. The site plan generator tool reduces the time needed to create construction drawings from days to hours, and with the integrated AI/ML system, potentially to minutes.

It should be noted that “cell site” refers specifically to sites supporting mobile communication, such as cellular networks (e.g., 4G, 5G, 6G, etc.). The cell site can include cell towers; rooftop antennas; small cells; distributed antenna systems (DAS); power supplies; Base Station Equipment Cabinets and Ancillary Equipment: Includes the enclosures and associated hardware necessary for housing and supporting base station components, ensuring proper operation and connectivity to the network infrastructure; Radio Units (RU): These units can be part of the base station, handling radio frequency signals; Microwave Links: Used for backhaul communication, especially in remote locations where fiber connections are unavailable; Power Generators and Backup Systems: To ensure continuous operation in case of power outages, including backup batteries and uninterruptible power supplies (UPS); Cooling Systems: Critical for maintaining the proper operating temperature for equipment, especially in high-performance environments; Cabling and Fiber Optic Connections: Integral to connecting different parts of the telecom network, ensuring fast and reliable data transmission. Network Routers and Switches: For managing data flow and ensuring seamless communication between different network segments; Security Systems: Surveillance cameras, fencing, and other equipment to secure the cell site; Satellite Dishes: For sites requiring satellite communication, such as remote or rural locations; Fiber NID Enclosures: Enclosures used to house fiber optic network interface devices (NIDs) for managing connections and ensuring secure fiber optic connections; Equipment and material grounding designs and plans; Steel platform support for ground cabinets; Electrical equipment H-Frame support; Foundation designs for ground equipment cabinets and generators; Electrical and Fiber utility routes; Ingress and egress access routes, easements and methods; Compound perimeter fencing types and designs; etc. The technologies described herein can also be used for “telecom sites,” which refer to any site supporting telecommunications infrastructure, which can include cell sites, fiber optic nodes, microwave relay stations, data centers, and broadcast towers. Examples of telecom sites can include facilities for internet backbone connectivity, fixed wireless access, satellite communications, or public safety networks.

It is appreciated that methods and systems in accordance with the present disclosure can include any combination of the aspects and features described herein. That is, methods and systems in accordance with the present disclosure are not limited to the combinations of aspects and features specifically described herein, but also may include any combination of the aspects and features provided.

The details of one or more implementations of the present disclosure are set forth in the accompanying drawings and the description below. Other features and advantages of the present disclosure will be apparent from the description and drawings, and from the claims.

Other embodiments of this aspect include corresponding computer systems, apparatus, computer program products, and computer programs recorded on one or more computer storage devices, each configured to perform the actions of the method. A system of one or more computers can be configured to perform particular operations or actions by virtue of having software, firmware, hardware, or a combination of them installed on the system that in operation causes or causes the system to perform the actions. One or more computer programs can be configured to perform particular operations or actions by virtue of including instructions that, when executed by data processing apparatus, cause the apparatus to perform the actions.

The foregoing and other embodiments can each optionally include one or more of the following features, alone or in combination. In some implementations, the method can include storing a construction plan template for cell sites in a cellular network, the construction plan template comprising a pre-defined layout of frames, each frame being assigned to include at least one of information or graphics, associated with cell site equipment for the cell site, in a specific location in the cell site construction plan. The method can also include storing a set of pre-defined design elements corresponding to available cell site equipment, the available cell site equipment comprising a plurality of tower or mounting structures, a plurality of antennas, a plurality of radio equipment, and a plurality of power systems. The method can also include receiving, from a user device, user input about a cell site in the cellular network, the user input comprising tower requirements, antenna requirements, and equipment requirements. The method can also include receiving, from the user device, a request to generate a cell site construction plan using the user input and the construction plan template. The method can also include, automatically in response to the request: retrieving a copy of the construction plan template to generate the cell site construction plan; identifying, using the user input, a subset of design elements from the set of pre-defined design elements, the subset of design elements comprising design elements corresponding to one of the plurality of tower or mounting structures, to one of the plurality of antennas, one of the plurality of radio equipment, and one of the plurality of power systems; populating a plurality of frames of the cell site construction plan with the subset of design elements. The method can also include sending the cell site construction plan to the user device.

In some implementations, the computing system is a cloud computing system, and the site plan generator tool is implemented in the cloud computing system.

Particular implementations of the subject matter described in this disclosure can be implemented so as to realize one or more of the following advantages. By providing the software tool and library of construction drawing templates and detailed design elements that facilitate automation of generating a cell site construction plan, the technologies described herein can enhance efficiency of cell site construction plan generation (i.e., reduce drafting time to 1 hour or less), enabling artificial intelligence (AI) and machine learning (ML) automations, streamline and standardize the development of cell site projects, reduced errors, enhanced collaboration among A&E firms, etc. Below are some additional advantages of the site plan generator tool:
1. Efficiency: By automating the drafting process, the site plan generator tool significantly reduces the time needed to create construction plans, completing them in under an hour.
2. AI/ML Automation: The integration of artificial intelligence and machine learning enhances the site plan generator tool's speed and optimizes the design process, further accelerating plan creation.
3. Standardization: Offering standardized templates and design elements, the site plan generator tool ensures consistent project output, helping avoid discrepancies across different teams.
4. Error Reduction: Automation and the use of standard templates minimize mistakes, cutting down on costly corrections and rework during construction.
5. Collaboration: The site plan generator tool fosters better communication and teamwork among architects and engineers by providing shared templates, streamlining the approval process.
6. Cloud-Based Updates: Hosted on the cloud, the system ensures that all firms have access to the most up-to-date templates and designs, with real-time updates.
7. Customizability: The site plan generator tool is adaptable to meet local regulatory requirements, offering flexibility for different regions and jurisdictions.

In short, the site plan generator tool enhances efficiency, minimizes errors, promotes collaboration, and ensures that construction plans are always current and compliant with local standards.
8. Cost Reductions; The site plan generator tool will minimize human drafting and engineering labor to reduce cost to the customer. AI can suggest more cost-effective solutions or detect areas where savings could be achieved, optimizing the overall budget.
9. Centralized Control; The site plan generator tool will maximize centralized control which will minimize the use of unapproved, inferior products in the design.
10. Automation of Repetitive Tasks: the site plan generator tool can handle repetitive tasks like drafting basic components, making it easier to create standard construction elements without manual effort.
11. Predictive Analytics for Future Needs: The site plan generator tool can predict future issues or challenges by analyzing data from similar past projects. This foresight can help in better planning and risk management, minimizing unexpected setbacks during construction.
12. Design for Sustainability: The site plan generator tool can be used to optimize designs for energy efficiency, sustainability, and environmental impact. For example, the site plan generator tool can suggest materials or layouts that promote better energy use, reduce waste, or improve the construction project's overall environmental footprint.
13. Integration with BIM (Building Information Modeling): The site plan generator tool can integrate seamlessly with BIM software, improving the 3D modeling and visualization of construction projects. This provides a more detailed and comprehensive view of the construction project before construction begins.
14. Bills of materials: The site plan generator tool can integrate with supply chain's materials lists to create a bill of materials to be ordered and a parts pull list far in advance of current manual processes which can be edited as necessary.
15. Requests for proposals: The site plan generator tool can create requests for proposals to be sent to construction contractors, and utility companies electronically and receive quotations which in turn can automatically produce purchase orders.
16. Utility applications: The site plan generator tool can automatically create utility applications and forward designs to the utility companies through their online methods.
17. Permit Packages: The site plan generator tool can assemble all engineering documentations and specifications into a single file that can be used for permit submittals.
18. Actual vs planned construction results: The site plan generator tool can use the information from final inspections (manual and drone) and compare the completed construction project against the planned design to determine deviations from the plans to determine contractor performance, suggest better future designs, and cost analysis.

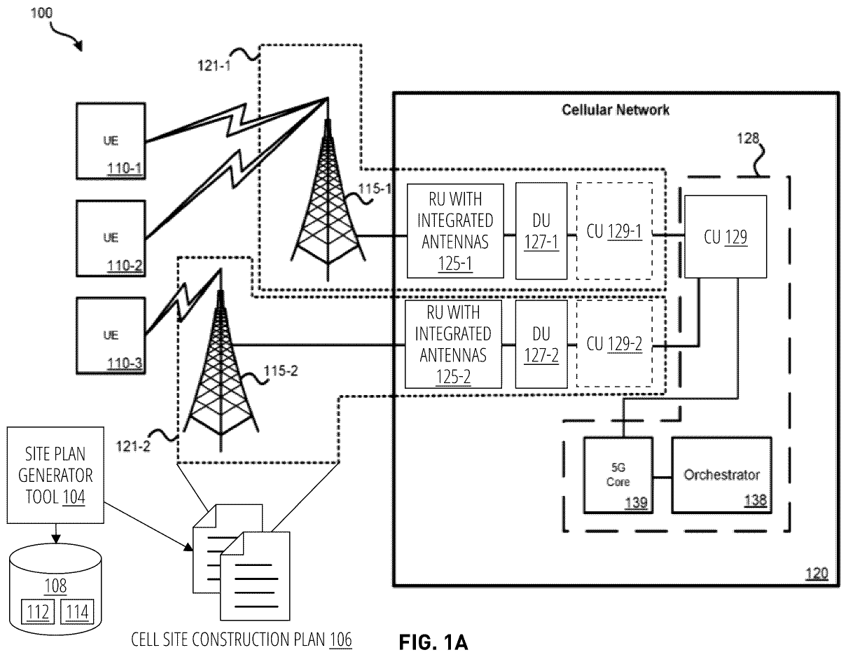

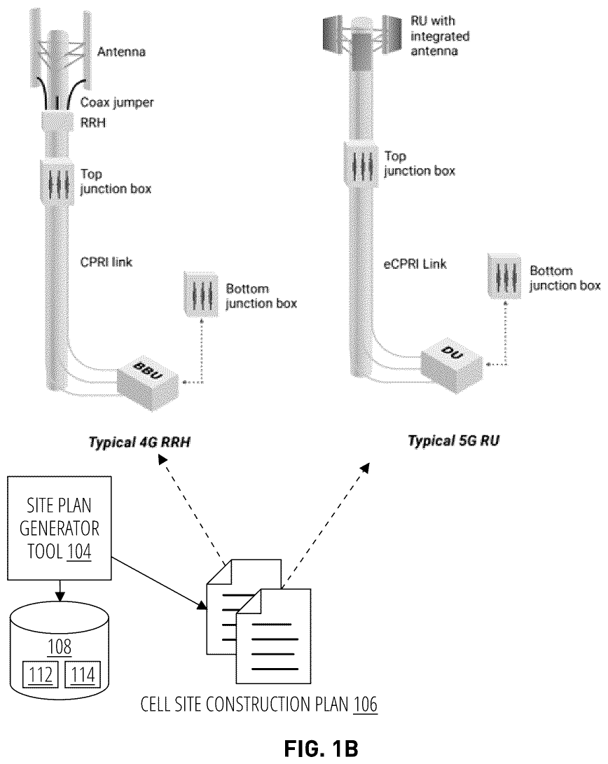

FIG. 1A is a block diagram of a cellular network system 100 (“system 100”) implementing a site plan generator tool 104 for generating a cell site construction plan 106 for a cell site in a cellular network system 100 according to at least one embodiment. FIG. 1A represents an embodiment of a cellular network which can accommodate a cloud-based architecture. System 100 can include a 5G New Radio (NR) cellular network; other types of cellular networks, such as 6G, 7G, etc. System 100 can include: UEs 110 (UE 110-1, UE 110-2, UE 110-3); base stations 121; cellular network 120; RU with integrated antennas 125 (“RUs 125”); distributed units 127 (“DUs 127”); CU 129 (“CU 129”); network core 139 (e.g., 5G core, 6G core), and orchestrator 138. FIG. 1A represents a component-level view. FIG. 1B illustrates a tower with a typical 4G Remote Radio Head (RRH) and a tower with a typical 5G RU. As illustrated in the tower for a typical 5G RU, the RU can be attached to the tower like the RRH in the 4G RRH, but for massive MIMO, the RU and antennas are integrated at the tower. In an Open Radio Access Network (O-RAN), because components can be implemented as specialized software executed on general-purpose hardware, except for components that need to receive and transmit radio frequency (RF), the functionality of the various components can be shifted among different servers. For at least some components, the hardware may be maintained by a separate cloud-service provider, to accommodate where the functionality of such components is needed.

UE 110 can represent various types of end-user devices, such as cellular phones, smartphones, cellular modems, cellular-enabled computerized devices, sensor devices, gaming devices, access points (APs), CPE (Custom Premises Equipment), any computerized device capable of communicating via a cellular network, etc. Generally, UE can represent any type of device that has an incorporated 5G interface, such as a 5G modem. Examples can include sensor devices, Internet of Things (IoT) devices, manufacturing robots; unmanned aerial (or land-based) vehicles, network-connected vehicles, etc. Depending on the location of individual UEs, UE 110 may use RF to communicate with various base stations of cellular network 120. As illustrated, two base stations are illustrated: base station 121-1 can include: structure 115-1, RU with integrated antennas 125-1, and DU 127-1. The RU with integrated antennas 125 couple to the DU 127 through an enhanced Common Public Radio Interface (eCPRI) fronthaul. Each of the DUs 127-1 and 127-2 can be coupled to a CU 129. In another embodiment, the base station 121-1 can include: structure 115-1, RU with integrated antennas 125-1, DU 127-1, and CU 129-1. Structure 115-1 may be any structure to which one or more antennas (not illustrated) of the base station are mounted. Structure 115-1 may be a dedicated cellular tower, a building, a water tower, or any other human-made or natural structure to which one or more antennas can reasonably be mounted to provide cellular coverage to a geographic area. Similarly, base station 121-2 can include: structure 115-2, RU with integrated antennas 125-2, and DU 127-2. As described above, each of the DUs 127-1 and 127-2 can be coupled to a CU 129. In another embodiment, the base station 121-2 can include: structure 115-2, RU with integrated antennas 125-2, DU 127-2, and CU 129-2.

Real-world implementations of system 100 can include many (e.g., thousands) of base stations and many CUs and network core 139. BS 121 can include one or more antennas that allow RUs 125 to communicate wirelessly with UEs 110. RUs 125 can represent an edge of cellular network 120 where data is transitioned to wireless communication. The radio access technology (RAT) used by RU 125 may be 5G New Radio (NR), 6G NR, or some other RAT. The remainder of cellular network 120 may be based on an exclusive 6G architecture, an exclusive 5G architecture, a hybrid 4G/5G architecture, a 4G architecture, or some other cellular network architecture. Base station equipment may include an RU (e.g., RU with integrated antennas 125-1), a DU (e.g., DU 127-1), and a CU (e.g., CU 129-1).

One or more RUs, such as RU with integrated antennas 125-1, may communicate with DU 127-1. As an example, at a possible cell site, three RUs may be present, each connected with the same DU. Different RUs may be present for different portions of the spectrum. For instance, a first RU may operate on the spectrum in the citizens broadcast radio service (CBRS) band while a second RU may operate on a separate portion of the spectrum, such as, for example, band 77(n77 ). A typical massive MIMO band is TDD, including n48 (CBRS) and n77 (C-band). One or more DUs, such as DU 127-1, may communicate with CU 129-1. Collectively, an RU, DU, and CU create a gNodeB, which serves as the radio access network (RAN) of cellular network 120. CU 129 can communicate with network core 139. The specific architecture of cellular network 120 can vary by embodiment. The cellular network 120 can include antennas and UEs. Edge cloud server systems outside of cellular network 120 may communicate, either directly, via the Internet, or via some other network, with components of cellular network 120. For example, DU 127-1 may be able to communicate with an edge cloud server system without routing data through CU 129-1 or network core 139. Other DUs may or may not have this capability.

While FIG. 1A illustrates various components of cellular network 120, other embodiments of cellular network 120 can vary the arrangement, communication paths, and specific components of cellular network 120. While RU 125 may include specialized radio access componentry to enable wireless communication with UE 110, other components of cellular network 120 may be implemented using either specialized hardware, specialized firmware, and/or specialized software executed on a general-purpose server system. In an O-RAN arrangement, specialized software on general-purpose hardware may be used to perform the functions of components such as DU 127, CU 129, and network core 139. Functionality of such components can be co-located or located at disparate physical server systems. For example, certain components of network core 139 may be co-located with components of CU 129.

In a possible virtualized O-RAN implementation, CU 129, network core 139, and/or orchestrator 138 can be implemented virtually as software being executed by general-purpose computing equipment, such as in a data center of a cloud-computing platform, as detailed herein. Therefore, depending on needs, the functionality of a CU 129, and/or network core 139 may be implemented locally to each other and/or specific functions of any given component can be performed by physically separated server systems (e.g., at different server farms). For example, some functions of a CU may be located at a same server facility as where the DU is executed, while other functions are executed at a separate server system. In the illustrated embodiment of system 100, the site plan generator tool 104 can be executed as specialized software executed by underlying general-purpose computer servers. The site plan generator tool 104 may be executed on a third-party cloud-based computing platform or a cloud-based computing platform operated by the same entity that operates the RAN. A cloud-based computing platform may have the ability to devote additional hardware resources to the site plan generator tool 104 or implement additional instances of such components when requested.

Kubernetes, or some other container orchestration platform, can be used to create and destroy the logical CU or core units and subunits as needed for the cellular network 120 to function properly. Kubernetes allows for container deployment, scaling, and management. As an example, if cellular traffic increases substantially in a region, an additional logical CU or components of a CU may be deployed in a data center near where the traffic is occurring without any new hardware being deployed. (Rather, processing and storage capabilities of the data center would be devoted to the needed functions.) When the need for the logical CU or subcomponents of the CU no longer exists, Kubernetes can allow for removal of the logical CU. Kubernetes can also be used to control the flow of data (e.g., messages) and inject a flow of data to various components. This arrangement can allow for the modification of nominal behavior of various layers.

The deployment, scaling, and management of such virtualized components can be managed by orchestrator 138. Orchestrator 138 can represent various software processes executed by underlying computer hardware. Orchestrator 138 can monitor cellular network 120 and determine the amount and location at which cellular network functions should be deployed to meet or attempt to meet service level agreements (SLAs) across slices of the cellular network 120.

Orchestrator 138 can allow for the instantiation of new cloud-based components of cellular network 120. As an example, to instantiate a new core function, orchestrator 138 can perform a pipeline of calling the core function code from a software repository incorporated as part of, or separate from, cellular network 120; pulling corresponding configuration files (e.g., helm charts); creating Kubernetes nodes/pods; loading the related core function containers; configuring the core function; and activating other support functions (e.g., Prometheus, instances/connections to test tools).

Components such as DUs 127, CU 129, orchestrator 138, and network core 139 may include various software components that are required to communicate with each other, handle large volumes of data traffic, and are able to properly respond to changes in the cellular network 120.

The network core 139 (e.g., 5G core or 6G core), which can be physically distributed across data centers or located at a central national data center (NDC), can perform various core functions of the cellular network 120. The network core 139 can include: network resource management components; policy management components; subscriber management components; and packet control components. Individual components may communicate on a bus, thus allowing various components of network core 139 to communicate with each other directly. The network core 139 is simplified to show some key components. Implementations can involve additional other components.

The network core 139 may reside on a cloud computing platform. While from a client's or user's point of view, the “cloud” can be envisioned as an ephemeral computing workspace that occupies no physical space, in reality, a cloud computing platform is an interconnected group of data centers throughout which computing and storage resources are spread. Therefore, data centers may be scattered geographically and can provide redundancy.

In some embodiments, the system 100 (or cellular network 120) can include a site plan generator tool 104 that generates a cell site construction plan 106 for one or more cell sites in the system 100 where the base station equipment 121, etc., can be deployed. The site plan generator tool 104 can be executed by a computing system, such as a cloud computing system. That is separate from the computing systems used to implemented the cellular network 120. In other embodiments, the site plan generator tool 104 can be implemented as part of the computing systems used for the cellular network 120. In at least one embodiment, the site plan generator tool 104 can reside in a private subnet of a virtual private cloud (VPC), the private subnet being associated with an account. In other embodiments, the site plan generator tool 104 can be implemented in other locations associated with a cellular network system 100 (or cellular network 120). The site plan generator tool 104 can use a data store 108 that stores one or more site plan templates 112 and pre-defined design elements 114. In at least one embodiment, the data store 108 can be implemented in a cloud-based storage unit or a storage unit in a storage service, such as the Amazon Web Services (AWS) Simple Storage Service (S3) bucket.

In at least one embodiment, a computing system includes one or more processors, and one or more memories (e.g., data store 108) storing a site plan template 112, a set of pre-defined design elements 114 corresponding to available cell site equipment. The one or more memories also store instructions that, when executed by the one or more processors, configure the computing system to execute the site plan generator tool 104. The site plan generator tool 104 can perform, in an automated fashion, various operations, such as those described herein, including receiving user input and providing a cell site construction plan 106 based on the user input. The cell site construction plan 106 can be a construction drawing set. The site plan generator tool 104 can also interact with other code, programs, applications, scripts, such as a CAD program or CAD tool for creating and updating the pre-defined design elements 114 as described herein.

There can be some general components of the cell site construction plan 106, including, for example: location overview, site layout, tower or structure design, antenna configuration, equipment shelter or cabinet, power and connectivity, safety and security, environmental considerations, regulatory Compliance Details, construction notes, or the like. The location overview can include geographic details of the site, including address, latitude, and longitude, topographical features and surrounding land use (residential, commercial, or industrial). The site layout can include a scaled drawing showing the entire property and placement of the cell site infrastructure. The site layout can include key features such as access roads, fences, gates, and utility easements. The site layout can specify orientation and distances from property boundaries, nearby buildings, and other structures. The tower or structure design can include specifications for the tower type (monopole, lattice, guyed, or rooftop mount), height of the structure, load capacity for antennas, radios, and other equipment, lightning protection and grounding systems. The antenna configuration can include the placement and orientation of antennas on the tower or structure, specifications for tilt, azimuth, and height to optimize signal propagation. The equipment shelter or cabinet can specify the design of enclosures for baseband units, power systems, batteries, and backup generators, climate control features (e.g., HVAC systems) for equipment protection, or the like. The power and connectivity can specify the connection to the electrical grid and backup power systems (generators or batteries). The power and connectivity can also specify details on network backhaul connectivity (fiber, microwave, or satellite links). The safety and security can specify safety features like anti-climb measures and warning signs, fencing or barriers to restrict unauthorized access, fire prevention systems, where required, or the like. The environmental considerations can include landscaping or camouflage features (e.g., stealth designs like faux trees or architectural integration), drainage and soil stabilization plans for ground-mounted towers, or the like. The regulatory compliance details can include zoning and building code information, environmental impact measures, such as wildlife protection or noise reduction, compliance with FAA regulations if near airports, or the like. The construction notes can include materials and specifications for construction, phasing and timeline for site preparation, tower erection, and equipment installation, or the like. Managing the information for the various components for producing the cell site construction plan 106 can be tedious and cumbersome for manual processes. The site plan generator tool 104 can be used to receive user input with information about the cell site and automatically generate the cell site construction plan 106 with information for any of these components described above.

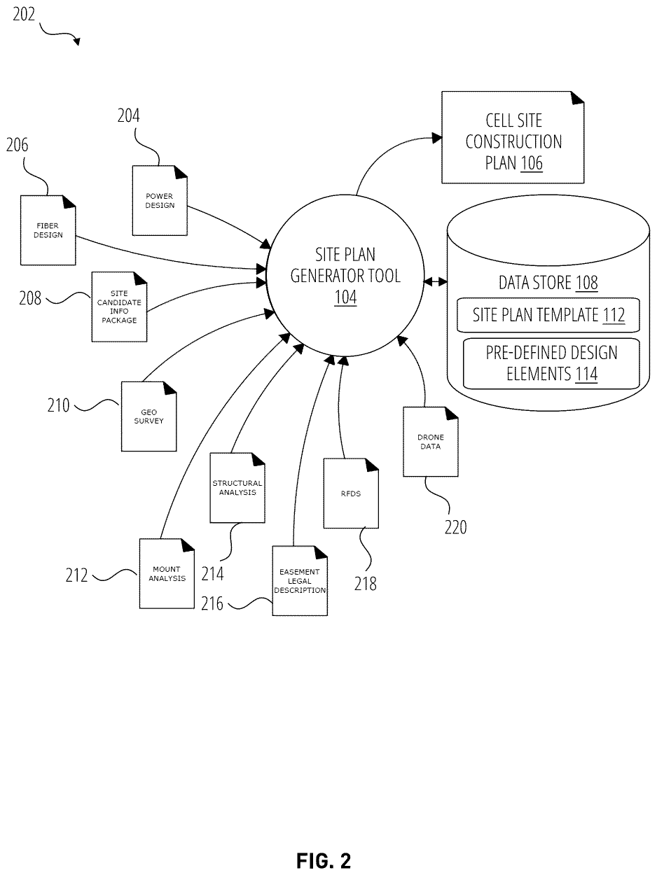

In at least one embodiment, the site plan generator tool 104 receives, from a user device, user input about a cell site of a cellular network. The user device can be a computer used by an A&E firm. The user input can include tower requirements, antenna requirements, and equipment requirements. The user input can be in the form of one or more files, such as the files illustrated and described below with respect to FIG. 2. The site plan generator tool 104 can receive, from the user device, a request to generate a cell site construction plan 106 using the user input. Automatically in response to the request, the site plan generator tool 104 can retrieve a copy of the site plan template 112 to generate the cell site construction plan 106. The site plan template 112 can include a pre-defined layout of frames, each frame being assigned to include at least one of information or graphics, associated with cell site equipment for the cell site, in a specific location in the cell site construction plan 106. The cell site equipment can include a tower or mounting structure, an antenna, a radio equipment, and a power system for the cell site. Automatically in response to the request, the site plan generator tool 104 can identify, using the user input, a subset of design elements from the set of pre-defined design elements 114. The subset of design elements includes design elements corresponding to the tower or mounting structure, the antenna, the radio equipment, and the power system. Automatically in response to the request, the site plan generator tool 104 can populate one or more frames of the cell site construction plan 106 with the subset of design elements. The site plan generator tool 104 can send the cell site construction plan 106 to the user device.

In at least one embodiment, the site plan generator tool 104 can include an AI/ML system to facilitate one or more operations of the site plan generator tool 104. In at least one embodiment, the site plan generator tool 104 includes one or more trained AI/ML models to extract site information and an equipment schedule from the user input and identify the subset of pre-defined design elements 114 corresponding to a tower or mounting structure, an antenna, a radio equipment, and a power system that meet the tower requirements, the antenna requirements, and the equipment requirements. In at least one embodiment, the site plan generator tool 104 can extract a plurality of features from the user input and identify the subset of pre-defined design elements 114 using an AI/ML model and the plurality of features. An output of the AI/ML model includes the cell site construction plan 106 or portions of the cell site construction plan 106. In at least one embodiment, the site plan generator tool 104 is considered an AI automation system that can receive user input and generate the cell site construction plan 106 using the user input in an automated fashion. In some cases, the AI automation system can generate portions or contents of one or more frames of the cell site construction plan 106.

In at least one embodiment, the user input includes antenna requirements specified in an RFDS. The site plan generator tool 104, to identify the subset of pre-defined design elements 114, can determine antenna dimensions and type of an antenna using the RFDS and the tower requirements, and identify a first pre-defined design element corresponding to the antenna type. The site plan generator tool 104 can populate a first frame with the first pre-defined design element having the antenna dimensions. The first frame can include a first label identifying an antenna category and a first visibility state comprising the antenna type, the antenna dimensions, and one or more views of the antenna.

In at least one embodiment, in order to identify the subset of pre-defined design elements 114, the site plan generator tool 104 can analyze the user input to extract site information and an equipment schedule. The site plan generator tool 104 can generate, using the site information and the equipment schedule, one or more dynamic blocks, each dynamic block corresponding to one of the set of pre-defined design elements 114. Each of the dynamic blocks can be defined by one or more modifiable parameters, one or more actions, one or more visibility states, look-up tables (LUTs), and one or more constraints. The one or more modifiable parameters can define specific properties, such as distance, angle, visibility, alignment, or the like. For example, a dynamic block for a door can include parameters for width and swing direction. The dynamic blocks can also specify one or more fixed parameters that are not modifiable. example of a modifiable parameter is The one or more actions can be linked to one or more modifiable parameters that control behavior of the respective dynamic block. Examples can include stretch, rotate, flip, move, or scale parts of the block dynamically. The visibility states allow the respective dynamic block to display different configurations or appearances. A single dynamic block for a table can have various sizes as visibility states. The LUTs enable predefined sets of values for the one or more modifiable parameters to ensure consistent modifications when the one or more modifiable parameters change. The LUTs make it easier to apply consistent modifications. The one or more constraints can be used to maintain geometric relationships within the respective dynamic block to ensure it adjusts correctly when the one or more modifiable parameters change. Once the site plan generator tool 104 generates the one or more dynamic blocks, the site plan generator tool 104 can populate one or more frames in the cell site construction plan 106 with the one or more dynamic blocks.

The use of dynamic blocks can reduce the need to maintain multiple blocks for variations of an object, improving the efficiency of generating the cell site construction plans. The use of dynamic blocks also provide flexibility by allowing easy block instance modifications to fit specific requirements. The use of dynamic blocks can provide consistency across a project or multiple projects by providing standardized design elements. The dynamic blocks can be used for the various cell site equipment, such as the tower or mounting structure, the antenna, the radio equipment, the power system, or the like. Other examples can include architectural symbols like doors, windows, or furniture with variable sizes, engineering components like bolts, beams, or pipes with different dimensions, landscaping elements such as trees or shrubs with adjustable scales, or the like.

In at least one embodiment, the dynamic blocks can be created and edited using a block editor in a CAD program. The site plan generator tool 104 can use the CAD program to define parameters, actions, and constraints to build custom, adaptable blocks for various projects. In at least one embodiment, the site plan generator tool 104 can generate the one or more dynamic blocks by identifying, using the user input, a first set of values from the predefined sets of values in the look-up tables of the respective dynamic block and updating the one or more modifiable parameters with the first set of values using the block editor with the one or more constraints that causes the CAD program to modify the corresponding pre-defined design element to an updated design element. The site plan generator tool 104 can then update the visibility state with the updated design element.

In at least one embodiment, the dynamic blocks, corresponding to the pre-defined design elements 114, can include a first dynamic block corresponding to a plurality of types for the tower or mounting structures, a second dynamic block corresponding to a plurality of types for the antenna, a third dynamic block corresponding to a plurality of types for the radio equipment, a fourth dynamic block corresponding to a plurality of types of antenna mounts for the antenna, etc.

In at least one embodiment, site plan generator tool 104 can automatically recognize information from the user input to populate one or more title blocks of the cell site construction plan 106. The one or more title blocks can be assigned to specific locations in the cell site construction plan 106. In at least one embodiment, the user input includes location information. The site plan generator tool 104 can populate a first frame of the cell site construction plan 106 with the location information about the cell site, the first frame being assigned to a specific location in the cell site construction plan 106.

In at least one embodiment, the cell site construction plan 106 includes a first frame of the plurality of frames that is assigned a first equipment detail category, and a second frame of the plurality of frames that is assigned a second equipment detail category. The first frame includes a first label identifying the first equipment detail category and a first visibility state comprising a first equipment name of a first equipment, first equipment details of the first equipment, and one or more graphical views of the first equipment. The second frame includes a second label identifying the second equipment detail category and a second visibility state comprising a second equipment name of a second equipment, second equipment details of the second equipment, and one or more views of the second equipment.

In at least one embodiment, the site plan generator tool 104 can receive, from the user device, additional user input to change i) one or more parameters of the cell site equipment or ii) a view of one or more of the subset of design elements in one or more frames of the pre-defined layout of frames. The one or more parameters can include an equipment name, equipment details, or equipment dimensions associated with one or more of the subset of design elements. The site plan generator tool 104 can update, using the additional user input, i) the one or more of the subset of design elements in the pre-defined layout of frames or ii) the view of the one or more of the subset of design elements in the one or more frames of the pre-defined layout of frames of the cell site construction plan 106.

As described above, the site plan generator tool 104 can receive one or more files as user input, such as illustrated and described below with respect to FIG. 2.

FIG. 2 illustrates a site plan generator tool 104 receiving user input and providing a cell site construction plan 106 according to at least one embodiment. The user input can include one or more files, including one or more power design files 204, one or more fiber design files 206, one or more site candidate information package files 208, one or more geological survey files 210, one or more mount analysis files 212, one or more structural analysis files 214, one or more easement legal description files 216, one or more radio frequency data sheets (RFDSes) 218, and drone data files 220. The user input can include other files not specifically illustrated and described in this embodiment. The power design files 204 can include a detailed plan showing how electrical power is distributed to telecom sites, including backup systems, power requirements, and safety standards. In at least one embodiment, the power design files 204 includes power design information or power design data that indicates how electrical power is distributed to the cell site. The fiber design files 206 can include a blueprint outlining the layout and specifications of fiber-optic cables, including routes, splice points, and equipment, ensuring high-speed data transmission for telecom networks. In at least one embodiment, the fiber design files 206 includes fiber design information or fiber design data that includes layout and specification of fiber-optic cables for the cell site. The site candidate information package files 208 (also referred to as “site data”) can be one or more documents summarizing potential sites for telecom infrastructure, including location details, photos, access, and suitability for equipment installation. The site candidate information package files 208 can include potential locations for the cell site equipment at the cell site. The geological survey files 210 can include a geographic and topographic survey of a telecom site, detailing land elevations, boundaries, and environmental conditions for planning and construction purposes. In at least one embodiment, the geological survey files 210 includes geological survey data or geographic and topographic survey information of the cell site. The mount analysis files 212 can include an evaluation of mounting structures to ensure they can safely support antennas, considering weight, wind loads, and vibration. In at least one embodiment, the mount analysis files 212 includes antenna mount information to ensure mounting of the antenna on the tower or mounting structure. The structural analysis files 214 can include an engineering report assessing the structural integrity of a tower to ensure it can safely support antennas, cables, and other equipment under expected loads and environmental conditions. In at least one embodiment, the structural analysis files 214 includes structural analysis data or tower structural information about the tower or mounting structure. The easement legal description files 216 can include one or more legal documents defining the specific area of land granted for use in telecom infrastructure, including access rights and restrictions. In at least one embodiment, the easement legal description files 216 includes legal description data or legal description information defining a specific area of land granted for use by the cell site and access rights and restrictions on the specific area of land. The RFDSes 218 can include one or more technical documents detailing the radio frequency configurations, antenna parameters, and site settings for a specified or optimal network performance. In at least one embodiment, the RFDSes 218 includes radio frequency design specification data or The drone data files 220 can include aerial imagery and data collected by drones (or other aircrafts or space vehicles), used for site inspections, mapping, and planning, offering a comprehensive view of the area and infrastructure, including pre-mapping of the site. In at least one embodiment, the drone data files 220 includes image data of the cell site captured by a drone or other aircraft or space vehicle. In at least one embodiment, the drone data files 220 includes aerial imagery and data captured at the cell site.

As described above, the site plan generator tool 104 can receive any of the various files described above and generate the cell site construction plan 106 using the site plan template 112 and the pre-defined design elements 114 stored in the data store 108.

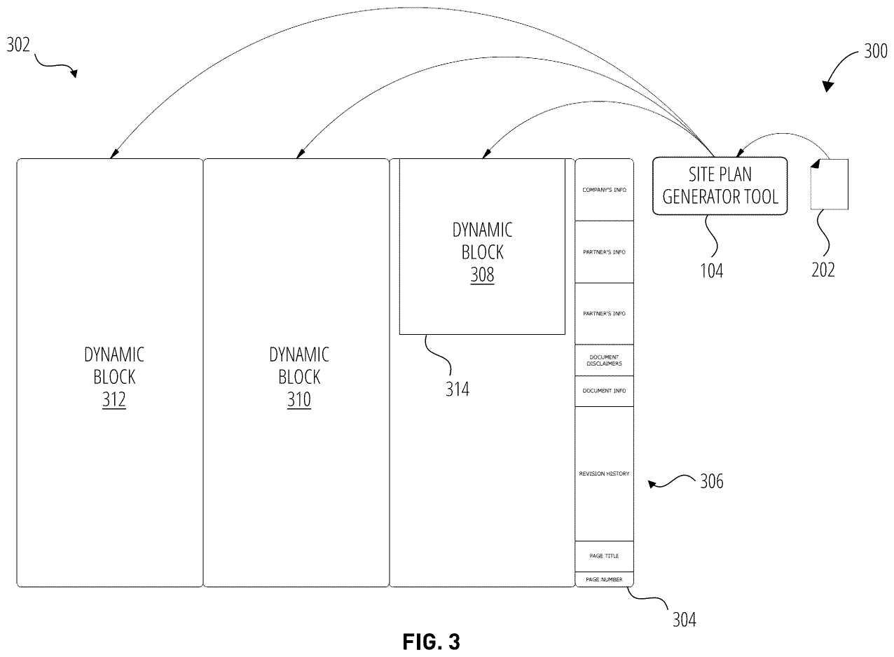

As described above, the site plan generator tool 104 can receive one or more files as user input and generate one or more dynamic blocks, such as illustrated and described below with respect to FIG. 3 to FIG. 8.

FIG. 3 illustrates a process 300 in which the site plan generator tool 104 uses a site plan template 304 and user input 202 to generate a cell site construction plan 302 for a cell site of a cellular network according to at least one embodiment. The user input 202 can be the same as, or similar to, the user input described above with respect to FIG. 1A to FIG. 2, including the power design files 204, fiber design files 206, site candidate information package files 208, geological survey files 210, mount analysis files 212, structural analysis files 214, easement legal description files 216, RFDSes 218, drone data files 220, etc. The site plan template 304 can be the same as, or similar to, the site plan template 112 described above with respect to FIG. 1A to FIG. 2. The cell site construction plan 302 can be the same as, or similar to, the cell site construction plan 106 described above with respect to FIG. 1A to FIG. 2.

In at least one embodiment, the site plan generator tool 104 receives the user input 202 from a user device. In at least one embodiment, the site plan generator tool 104 receives an indication of where the user input 202 is stored and fetches the user input 202 in response to a request from a user. The site plan template 304 is similar to the site plan templates 112 described above. The site plan template 304 can include a pre-defined layout of frames, each frame being assigned to include at least one of information or graphics in a specific location in a cell site construction plan 302 being generated. In at least one embodiment, some of the frames can be assigned to display one or more title blocks 306. Examples of title blocks 306 can include company information, partner information (e.g., A&E firm's information), document disclaimers, document information, revision history, page title, page number, etc. In at least one embodiment, the title blocks 306 can include static data or information. In at least one embodiment, the title blocks 306 can be populated using information extracted from the user input 202.

In at least one embodiment, some of the frames can be assigned a dynamic block, such as dynamic block 308, dynamic block 310, and dynamic block 312, illustrated in FIG. 3. These dynamic blocks can include one or more pre-defined design elements. Locations of these dynamic blocks can be assigned or otherwise specified in the site plan template 304 such that the dynamic block for a given cell site equipment appears in the same place regardless of the A&E firm generating the cell site construction plan 302. For example, the dynamic block 308 can be for a cell site equipment that is assigned to a frame 314 at a specific location in the site plan template 304. As described above, the site plan template 304 can specify various components of the cell site construction plan 302 being generated, including, for example, location overview, site layout, tower or structure design, antenna configuration, equipment shelter or cabinet, power and connectivity, safety and security, environmental considerations, regulatory compliance details, construction notes, or the like.

As described above, the site plan generator tool 104 can automatically extract data or information from the user input 202 to automatically generate contents for the various frames of the site plan template 304.

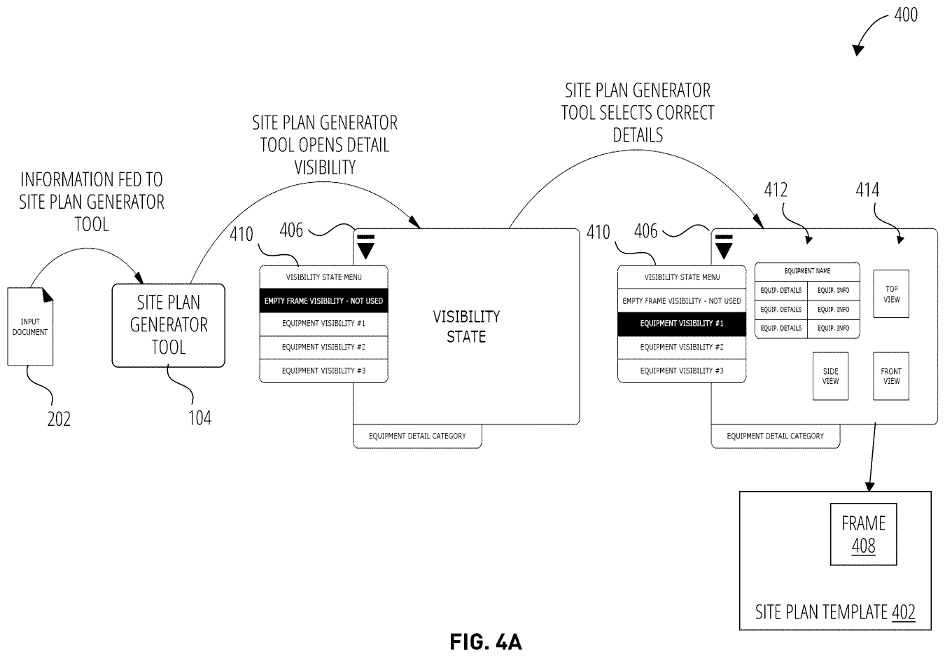

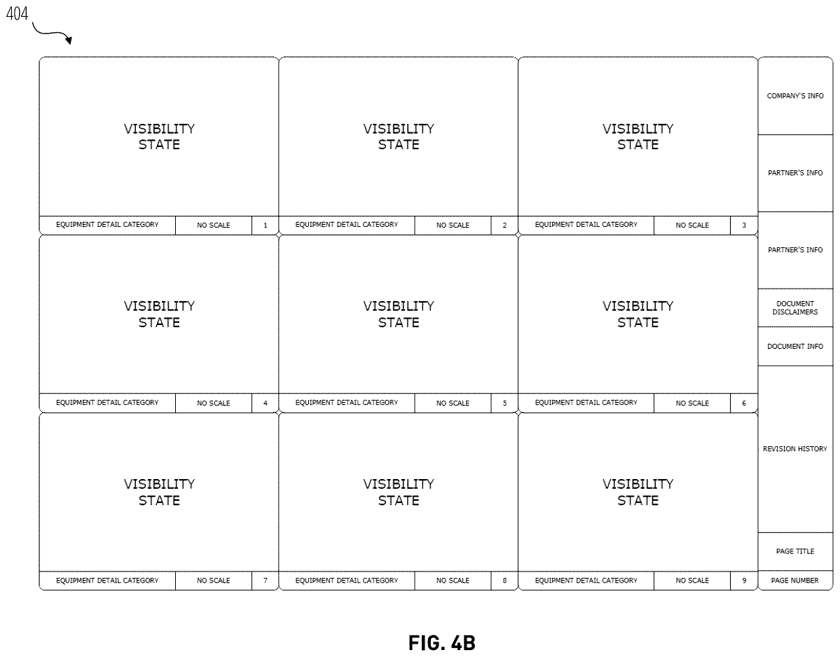

FIG. 4A illustrates a process 400 in which the site plan generator tool 104 generates a dynamic block 406 for a frame 408 in a site plan template 402 when generating a cell site construction plan 404 for a cell site of a cellular network according to at least one embodiment. The user input 202 can be the same as, or similar to, the user input described above with respect to FIG. 1A to FIG. 2 and user input 202 of FIG. 3. The site plan template 402 can be the same as, or similar to, the site plan template 112 of FIG. 1A to FIG. 2 or the site plan template 304 of FIG. 3. The cell site construction plan 404 can be the same as, or similar to, the cell site construction plan 106 of FIG. 1A to FIG. 2 or the cell site construction plan 302 of FIG. 3.

In at least one embodiment, the site plan generator tool 104 receives the user input 202 from a user device. In at least one embodiment, the site plan generator tool 104 receives an indication of where the user input 202 is stored and fetches the user input 202 in response to a request from a user. The site plan template 402 can include a pre-defined layout of frames, each frame being assigned to include at least one of information or graphics in a specific location in a cell site construction plan 404 being generated. As illustrated in FIG. 4A, the site plan template 402 includes a frame 408 that is populated with the dynamic block 406 that is generated by the site plan generator tool 104. The site plan generator tool 104 can extract information from the user input 202 to generate the dynamic block 406. To generate the dynamic block 406, the site plan generator tool 104 can open detail visibility of the dynamic block 406. The dynamic block 406 can include a visibility state menu with different items to select for the respective cell site equipment (e.g., tower structure). In this example, the visibility state menu includes four choices: empty frame visibility—not used; equipment visibility #1; equipment visibility state #2; and equipment visibility state #3. The “not used” item can be selected by default. Using information extracted from the 202, the dynamic block 406 can select one of the items in the visibility state menu 410 to select the correct details for the cell site equipment. In this example, the equipment visibility #1 is selected. Selecting this item, the site plan generator tool 104 populates the dynamic block 406 with equipment name and details 412 and one or more views 414 of the cell site equipment. The equipment name, details, and views can be populated with the specific values determined from the user input 202. The site plan template 402 can specify which views to display in a visibility state of the dynamic block 406. The site plan generator tool 104 can also populate the name or type of the equipment detail category for the respective cell site equipment associated with the dynamic block 406 as illustrated in FIG. 4A. Once the dynamic block 406 is generated, the site plan generator tool 104 can populate the frame 408 of the site plan template 402 with the dynamic block 406. This process 400 can be repeated for each frame of the site plan template 402 to generate the cell site construction plan 404, as illustrated in FIG. 4B.

FIG. 4B illustrates an example cell site construction plan 404 with multiple dynamic blocks generated by the site plan generator tool 104 according to at least one embodiment. The cell site construction plan 404 illustrated in FIG. 4B includes nine frames populated with nine dynamic blocks generated by the site plan generator tool 104. Each frame identifies the equipment detail category, a scale, and a frame index. The cell site construction plan 404 also includes title blocks.

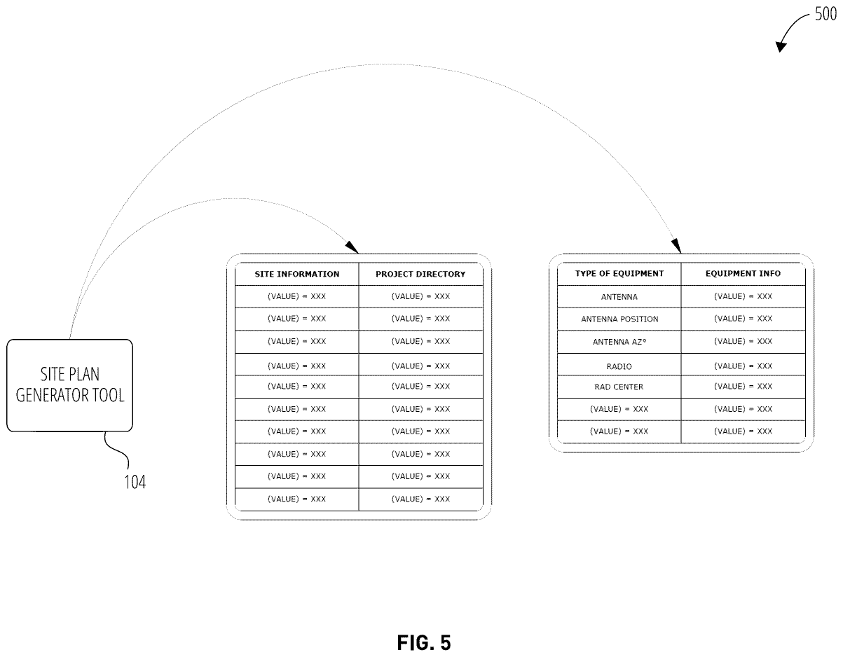

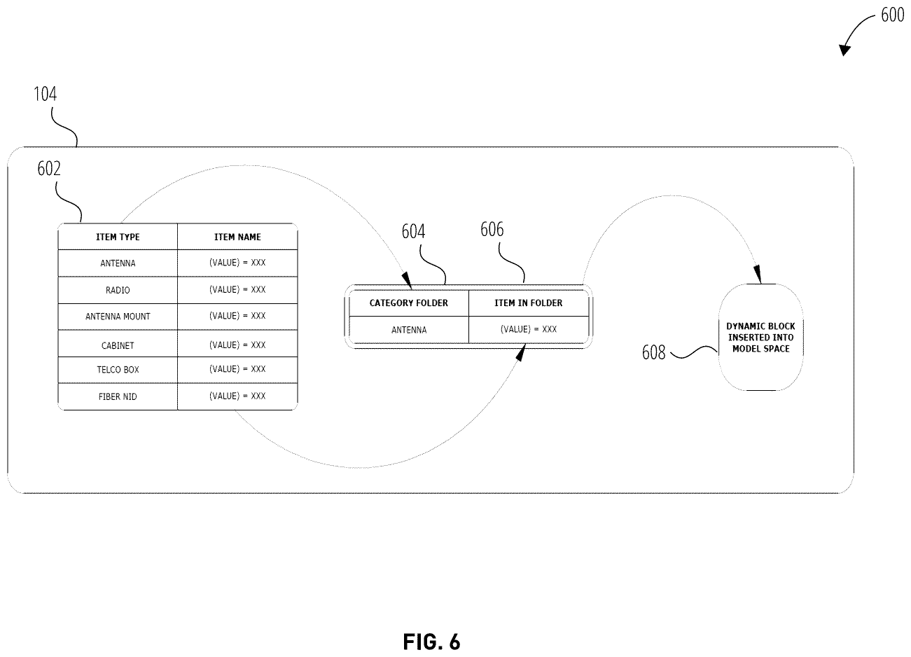

FIG. 5 illustrates a process 500 in which the site plan generator tool 104 analyzes user input and populates look-up tables with site information and equipment schedules according to at least one embodiment. The site plan generator tool 104 can receive or retrieve the user input as described above with respect to FIG. 2 to FIG. 4B. The site plan generator tool 104 analyzes the user input and extracts information to populate two LUTs, including LUT 502 and LUT 504. LUT 502 can include site information and a project directory. LUT 504 can include an equipment scheduling, which specifies various types of equipment and corresponding values for the various equipment. The LUT 502 and LUT 504 can be used by the site plan generator tool 104 to generate dynamic blocks, such as described above with respect to FIG. 4A to FIG. 4B. For example, when generating a dynamic block for an antenna, the site plan generator tool 104 can use the values in LUT 504 to select the appropriate antenna and parameters for the antenna. Similarly, the site plan generator tool 104 can use the values for other equipment types to generate other dynamic blocks. The site plan generator tool 104 can use the site information or project directory in the LUT 502 to populate contents of the dynamic blocks, the title blocks, or both. Similarly, the site plan generator tool 104 can use the information in the LUT 502, the LUT 504, to populate other information in the pre-defined layout of frames when automatically generating the cell site construction plan. An example of using information in a LUT to generate a dynamic block is illustrated and described below with respect to FIG. 6.

FIG. 6 illustrates a process 600 in which the site plan generator tool 104 generates a dynamic block 608 using information in a LUT 602 according to at least one embodiment. As described above, information can be extracted and populated in one or more LUTs, such as LUT 602. The LUT 602 can include one or more rows of items of various types. Each row includes an item value. The site plan generator tool 104 can identify an item for a category folder 604. In this example, the item is an antenna. The site plan generator tool 104 can look up the item type in the LUT 602 and populate the category folder 604 with the item (i.e., antenna). The site plan generator tool 104 can also extract the value for the item from the LUT 602 for an item in folder 606. Using the category folder 604 and item in folder 606, the site plan generator tool 104 can generate the dynamic block 608 to be inserted into a frame of a site plan template (also referred to as model space). The site plan generator tool 104 can use the LUTs as a look up system for automating aspects of generating the cell site construction plan or portions of the cell site construction plan.

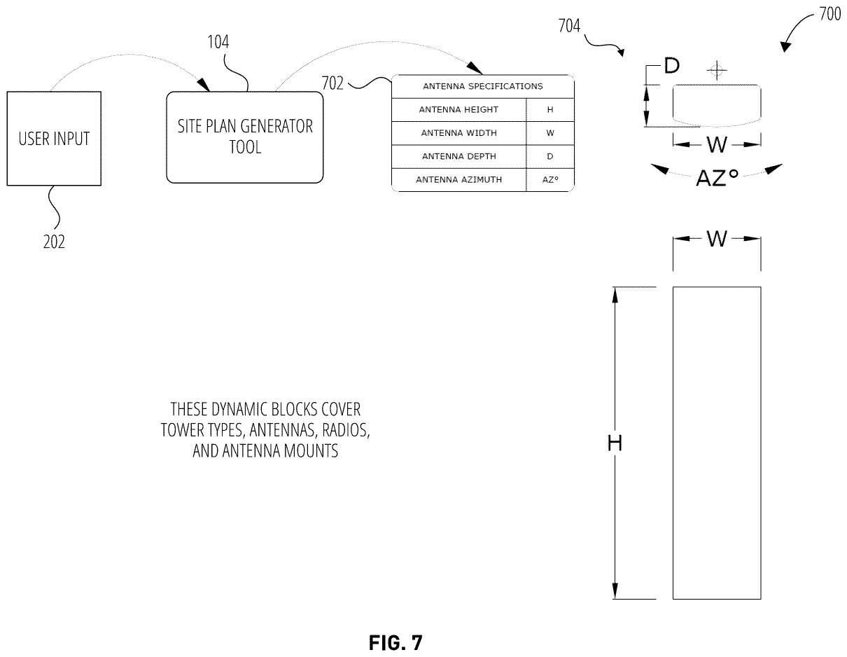

FIG. 7 illustrates a process 700 in which the site plan generator tool 104 generates antenna specifications for a dynamic block using user input according to at least one embodiment. The site plan generator tool 104 can receive or retrieve user input 202, similarly as described above with respect to FIG. 2 to FIG. 5. The site plan generator tool 104 analyzes the user input 202 and extracts antenna information to determine antenna specifications 702 for a dynamic block being generated. For example, the antenna specifications 702 can include an antenna height, an antenna width, an antenna depth, and an antenna azimuth. The antenna specifications 702 can also specify an antenna type. The antenna specifications 702 can correspond to one or more modifiable parameters of the dynamic block. Once the values for these antenna specifications 702 are determined, the site plan generator tool 104 can use these values to define the one or more modifiable parameters of the corresponding dynamic block. The site plan generator tool 104 can also generate one or more views 704 of the antenna with these antenna dimensions. These views 704 can be used for the dynamic block inserted into a frame of the pre-defined layout of frames in the site plan template.

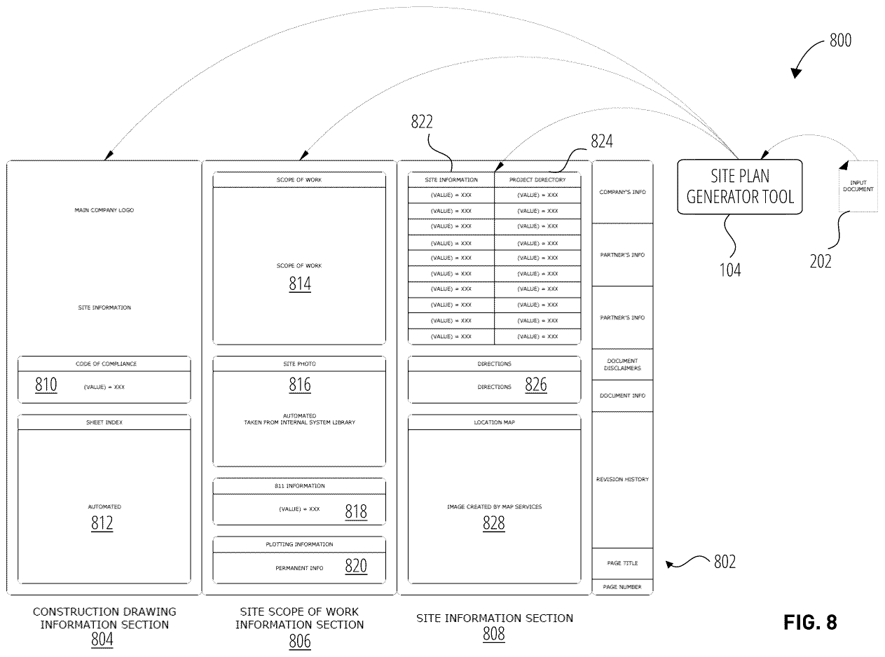

It should be noted that the site plan generator tool 104 can extract other information to determine specifications for other equipment for other dynamic blocks. These dynamic blocks can cover tower or mounting structure types, antennas, radio equipment, antenna mounts, or the like. The site plan generator tool 104 can extract other information to populate other aspects of a cell site construction plan, such as illustrated in FIG. 8.

FIG. 8 illustrates an example cell site construction plan 800 that is automatically generated by the site plan generator tool 104 based on user input 202 according to at least one embodiment. The cell site construction plan 800 includes title blocks 802, a construction drawing information section 804, a site scope of work information section 806, and a site information section 808. The construction drawing information section 804 can include a main company logic and other site information, a code of compliance section 810, and a sheet index 812. The sheet index 812 can be automated. The site scope of work information section 806 can include scope of work information 814, a site photo 816, utility information 818 (e.g., 811 information), and plotting information 820. The site photo 816 can be populated automatically. The site photo 816 can be taken from the image data received in the user input 202. The site photo 816 can be taken from an internal system library. The site information section 808 can include site information 822, a project directory 824, directions 826, and location map 828. The site information 822 and project directory 824 can be populated from the LUT 502 described above. The location map 828 can be created by map services.

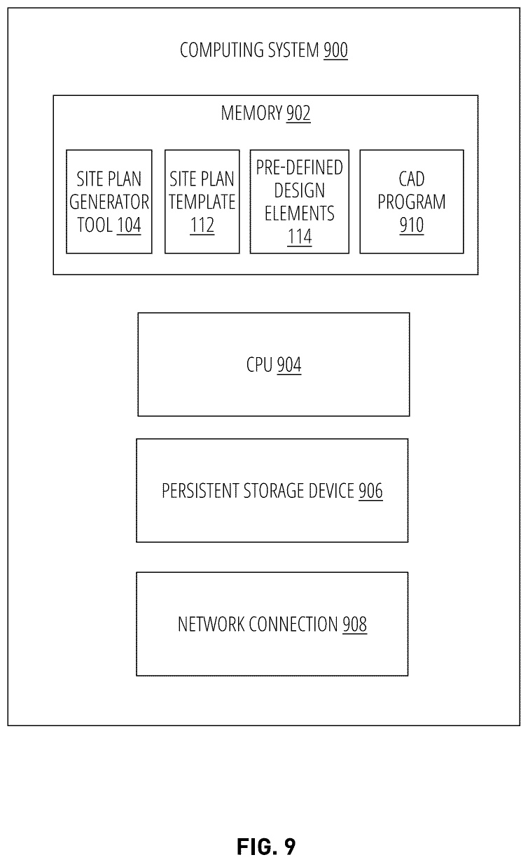

FIG. 9 is a block diagram depicting a computing system 900 on which at least a portion of the site plan generator tool 104 may operate, according to at least one embodiment. The computing system 900 may be: located on a network in a position to communicate with other network infrastructure components and user devices, in order to perform at least part of the functions required in generating cell site construction plans of a mobile network. Alternatively, the computing system 900 can be implemented as a standalone system from components of a cellular network. In various embodiments, the computing system 900 includes one or more of the following: a computer memory 902, a central processing unit (CPU) 904, a persistent storage device 906, and a network connection 908. The memory 902 may be used for storing programs and data while they are being used, including data associated with a cell site, an operating system including a kernel (not shown), and device drivers (not shown). The CPU 904 may be used for executing computer programs (not shown). The persistent storage device 906 may be a hard drive or flash drive for persistently storing programs and data. The network connection 908 may be used for connecting to one or more computer devices or other computer systems (not shown), to send or receive data, such as via the Internet or another network and associated networking hardware, such as switches, routers, repeaters, electrical cables and optical fibers, light emitters and receivers, radio transmitters and receivers, and the like, and to scan for and retrieve signals from other devices, components, or the like, and for connecting to one or more computer devices or other computer systems. In various embodiments, the computing system 900 additionally includes input and output devices, such as a keyboard, a mouse, display devices, etc.

While a computing system 900 configured as described may be used in some embodiments, in various other embodiments, the computing system 900 may be implemented using devices of various types and configurations, and having various components. The memory 902 may include the site plan generator tool 104 which contains computer-executable instructions that, when executed by the CPU 904, cause the computing system 900 to perform the operations and functions described herein. For example, the programs referenced above, which may be stored in computer memory 902, may include or be comprised of such computer executable instructions. The memory 902 may include the site plan generator tool 104. The memory 902 may also include the site plan template 112, the pre-defined design elements 114, a CAD program 910, or any combination thereof.

The site plan generator tool 104 performs the various operations described herein. In an example embodiment, the site plan generator tool 104 or computer-executable instructions stored on memory 902 of the computing system 900 are implemented using standard programming techniques. For example, the site plan generator tool 104 or computer executable instructions stored on memory 902 of the computing system 900 may be implemented as a “native” executable running on CPU 904, along with one or more static or dynamic libraries. In other embodiments, the site plan generator tool 104 or computer-executable instructions stored on memory 902 of the computing system 900 may be implemented as instructions processed by a virtual machine that executes as some other program.

The embodiments described above may also use synchronous or asynchronous client-server computing techniques. However, the various components may be implemented using more monolithic programming techniques as well, for example, as an executable running on a single CPU computer system, or alternatively decomposed using a variety of structuring techniques known in the art, including but not limited to, multiprogramming, multithreading, client-server, or peer-to-peer, running on one or more computer systems each having one or more CPUs. Some embodiments may execute concurrently and asynchronously, and communicate using message passing techniques. Equivalent synchronous embodiments are also supported. Also, other functions could be implemented or performed by each component/module, and in different orders, and by different components/modules, yet still achieve the functions of the computing system 900.

In addition, programming interfaces to the data stored as part of the site plan generator tool 104 can be available by standard mechanisms such as through C, C++, C#, Java, and web APIs; libraries for accessing files, databases, or other data repositories; through scripting languages such as JavaScript and VBScript; or through Web servers, File Transfer Protocol (FTP) servers, or other types of servers providing access to stored data. The site plan generator tool 104 may be implemented by using one or more database systems, file systems, or any other technique for storing such information, or any combination of the above, including implementations using distributed computing techniques.

Different configurations and locations of programs and data are contemplated for use with techniques described herein. A variety of distributed computing techniques are appropriate for implementing the components of the embodiments in a distributed manner including but not limited to TCP/IP sockets, RPC, RMI, HTTP, Web Services (XML-RPC, JAX-RPC, SOAP, and the like). Other variations are possible. Also, other functionality could be provided by each component/module, or existing functionality could be distributed amongst the components/modules in different ways, yet still achieve the functions of the computing system 900.

Furthermore, in some embodiments, some or all of the components/portions of the site plan generator tool 104, or functionality provided by the computer-executable instructions stored on memory 902 of the computing system 900 may be implemented or provided in other manners, such as at least partially in firmware or hardware, including, but not limited to, one or more application-specific integrated circuits (ASICs), standard integrated circuits, controllers (e.g., by executing appropriate instructions, and including microcontrollers or embedded controllers), field-programmable gate arrays (FPGAs), complex programmable logic devices (CPLDs), and the like. Some or all of the system components or data structures may also be stored as contents (e.g., as executable or other machine-readable software instructions or structured data) on a computer readable medium (e.g., as a hard disk; a memory; a computer network or cellular wireless network; or a portable media article to be read by an appropriate drive or via an appropriate connection, such as a DVD or flash memory device) so as to enable or configure non-transitory computer-readable medium or one or more associated computing systems or devices to execute or otherwise use or provide the contents to perform at least some of the described techniques. The non-transitory computer-readable storage medium includes instructions that when executed by a computing system, cause the computing system to perform operations described herein. Such computer program products may also take other forms in other embodiments. Accordingly, embodiments of this disclosure may be practiced with other computer system configurations.

In general, a range of programming languages may be employed for implementing any of the functionality of the servers, functions, user equipment, etc., present in the example embodiments, including representative implementations of various programming language paradigms and platforms, including but not limited to, object-oriented (e.g., Java, C++, C#, Visual Basic. NET, Smalltalk, and the like), functional (e.g., ML, Lisp, Scheme, and the like), procedural (e.g., C, Pascal, Ada, Modula, and the like), scripting (e.g., Perl, Ruby, PHP, Python, JavaScript, VBScript, and the like) and declarative (e.g., SQL, Prolog, and the like).

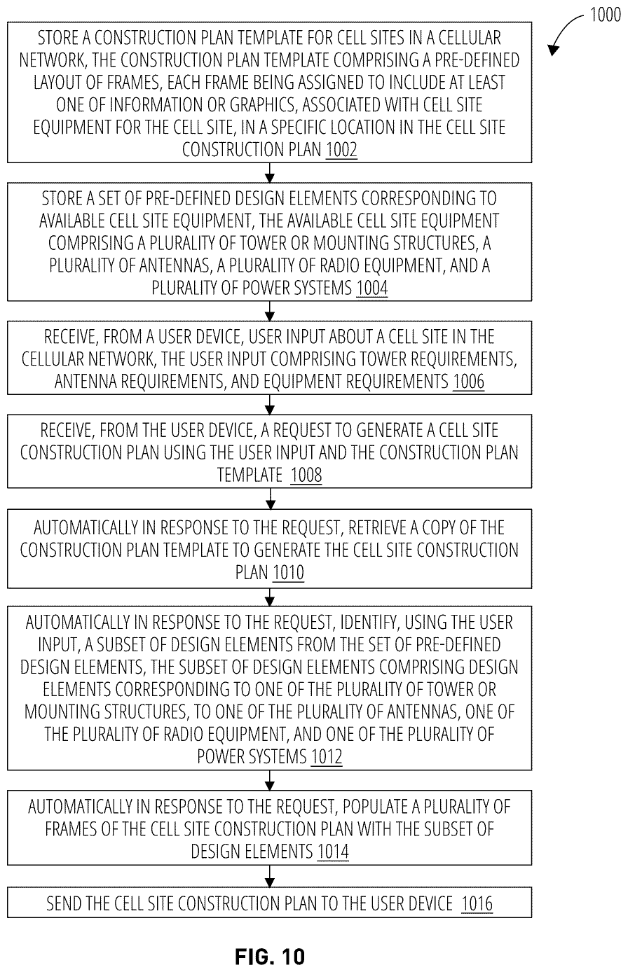

FIG. 10 is a flow chart of a method 1000 of automatically identifying a subset of design elements from a set of pre-defined design elements to populate frames of a cell site construction plan according to at least one embodiment. The method 1000 may be performed by processing logic that may comprise hardware (e.g., circuitry, dedicated logic, programmable logic, microcode, etc.), software (e.g., instructions run on a processing device to perform hardware simulation), or a combination thereof. In one embodiment, the method 1000 is performed by the site plan generator tool 104 of FIG. 1A to FIG. 9. In one embodiment, the method 1000 is performed by the computing system 900 of FIG. 9. The method 1000 can be performed by other computing systems described herein.

Referring to FIG. 10, the method 1000 begins with the processing logic storing a construction plan template for cell sites in a cellular network (block 1002). The construction plan template includes a pre-defined layout of frames, each frame being assigned to include at least one of information or graphics, associated with cell site equipment for the cell site, in a specific location in the cell site construction plan. At block 1004, the processing logic stores a set of pre-defined design elements corresponding to available cell site equipment. The available cell site equipment includes a plurality of tower or mounting structures, a plurality of antennas, a plurality of radio equipment, and a plurality of power systems. At block 1006, the processing logic receives, from a user device, user input about a cell site in the cellular network. The user input includes tower requirements, antenna requirements, and equipment requirements. At block 1008, the processing logic receives, from the user device, a request to generate a cell site construction plan using the user input and the construction plan template. At block 1010, the processing logic, automatically in response to the request, retrieves a copy of the construction plan template to generate the cell site construction plan. At block 1012, the processing logic, automatically in response to the request, identifies, using the user input, a subset of design elements from the set of pre-defined design elements, the subset of design elements comprising design elements corresponding to one of the plurality of tower or mounting structures, to one of the plurality of antennas, one of the plurality of radio equipment, and one of the plurality of power systems. At block 1014, the processing logic, automatically in response to the request, populates a plurality of frames of the cell site construction plan with the subset of design elements. At block 1016, the processing logic sends the cell site construction plan to the user device.

In a further embodiment, at block 1012, the processing logic identifies the subset of design elements using an AI/ML model trained to extract site information and an equipment schedule from the user input and identify the subset of design elements corresponding to the tower or mounting structure, the antenna, the radio equipment, and the power system that meet the tower requirements, the antenna requirements, and the equipment requirements.

In a further embodiment, at block 1012, the processing logic identifies the subset of design elements by analyzing the user input to extract site information and an equipment schedule, and generating, using the site information and the equipment schedule, one or more dynamic blocks, each dynamic block corresponding to one of the set of pre-defined design elements. Each of the dynamic blocks includes i) one or more modifiable parameters, ii) one or more actions that link to the one or more modifiable parameters that control behavior of the respective dynamic block, iii) visibility states that allows the respective dynamic block to display different configurations or appearances, iv) LUTs that enable predefined sets of values for the one or more modifiable parameters to ensure consistent modifications when the one or more modifiable parameters change, and v) one or more constraints that maintain geometric relationships within the respective dynamic block to ensure it adjusts correctly when the one or more modifiable parameters change. The plurality of frames can be populated with the one or more dynamic blocks.

In at least one embodiment, the antenna requirements includes an RFDS. The processing logic identifies the subset of design elements at block 1012 by determining antenna dimensions and type of an antenna using the RFDS and the tower requirements, and identifying a first pre-defined design element corresponding to the antenna type. The processing logic populates the plurality of frames by populating a first frame with the first pre-defined design element having the antenna dimensions. The first frame includes a first label identifying an antenna category and a first visibility state comprising the antenna type, the antenna dimensions, and one or more views of the antenna.

In at least one embodiment, the processing logic receives, from the user device, additional user input to change i) one or more parameters of the cell site equipment or ii) a view of one or more of the subset of design elements in one or more frames of the pre-defined layout of frames. The one or more parameters include an equipment name, equipment details, or equipment dimensions associated with one or more of the subset of design elements. The processing logic updates, using the additional user input, i) the one or more of the subset of design elements in the pre-defined layout of frames or ii) the view of the one or more of the subset of design elements in the one or more frames of the pre-defined layout of frames.

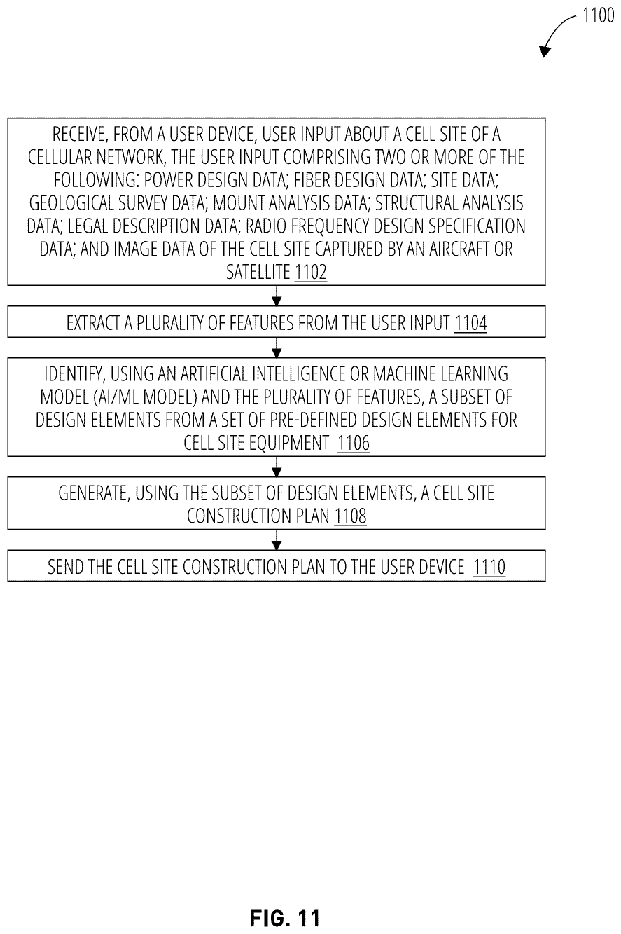

FIG. 11 is a flow chart of a method 1100 of identifying a subset of design elements using an AI/ML model to generate a cell site construction plan according to at least one embodiment. In one embodiment, the method 1100 is performed by the site plan generator tool 104 of FIG. 1A to FIG. 9. In one embodiment, the method 1100 is performed by the computing system 900 of FIG. 9. The method 1100 can be performed by other computing systems described herein.

Referring to FIG. 11, the method 1100 begins with the processing logic receiving, from a user device, user input about a cell site of a cellular network (block 1102). The user input can include two or more of the following: power design data; fiber design data; site data; geological survey data; mount analysis data; structural analysis data; legal description data; radio frequency design specification data; and image data of the cell site captured by an aircraft or satellite. At block 1104, the processing logic extracts a plurality of features from the user input. At block 1106, the processing logic identifies, using an AI/ML model and the plurality of features, a subset of design elements from a set of pre-defined design elements for cell site equipment. At block 1108, the processing logic generates, using the subset of design elements, a cell site construction plan. At block 1110, the processing logic sends the cell site construction plan to the user device.

In at least one embodiment, at block 1104, the processing logic extracts site information and an equipment schedule from the user input. The AI/ML model can be trained to identify the subset of design elements corresponding to the tower or mounting structure, the antenna, the radio equipment, and the power system that meet the tower requirements, the antenna requirements, and the equipment requirements.

In at least one embodiment, at block 1106, the processing logic analyzes the user input to extract site information and an equipment schedule. The processing logic generates, using the site information and the equipment schedule, one or more dynamic blocks, each dynamic block corresponding to one of the set of pre-defined design elements. Each of the dynamic blocks includes one or more modifiable parameters, one or more actions that link to the one or more modifiable parameters that control behavior of the respective dynamic block, visibility states that allows the respective dynamic block to display different configurations or appearances, LUTs that enable predefined sets of values for the one or more modifiable parameters to ensure consistent modifications when the one or more modifiable parameters change, and one or more constraints that maintain geometric relationships within the respective dynamic block when the one or more modifiable parameters change. The processing logic populates the plurality of frames with the one or more dynamic blocks.

In at least one embodiment, the user input includes any of the following: power design data; fiber design data; site data; geological survey data; mount analysis data; structural analysis data; legal description data; radio frequency design specification data; and image data of the cell site captured by a drone, wherein, to identify the subset of design elements.

In at least one embodiment, the processing logic receives, from the user device, additional user input to change i) one or more parameters of the cell site equipment or ii) a view of one or more of the subset of design elements in one or more frames of the pre-defined layout of frames, the one or more parameters comprises an equipment name, equipment details, or equipment dimensions associated with one or more of the subset of design elements. The processing logic updates, using the additional user input, i) the one or more of the subset of design elements in the predefined layout of frames or ii) the view of the one or more of the subset of design elements in the one or more frames of the pre-defined layout of frames.

In at least one embodiment, a non-transitory computer-readable storage medium includes instructions that when executed by a computing system, cause the computing system to perform operations as described herein.

In at least one embodiment, a computing system includes one or more processors, and one or more memories storing instructions that, when executed by the one or more processors, configure the computing system to perform operations as described herein.

Embodiments of the subject matter and the actions and operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively or in addition, the carrier may be an artificially-generated propagated Signal, e.g., a machine-generated electrical, optical, or electromagnetic Signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated Signal. A non-transitory computer-readable storage medium can include instructions that when executed by a computing system, cause the computing system to perform operations as described herein.

The term “data processing apparatus” encompasses all kinds of apparatus, devices, and machines for processing data, including by way of example a programmable processor, a computer, or multiple processors or computers. Data processing apparatus can include special-purpose logic circuitry, e.g., an FPGA (field programmable gate array), an ASIC (application-specific integrated circuit), or a GPU (graphics processing unit). The apparatus can also include, in addition to hardware, code that creates an execution environment for computer programs, e.g., code that constitutes processor firmware, a protocol stack, a database management system, an operating system, or a combination of one or more of them.

A computer program can be written in any form of programming language, including compiled or interpreted languages, or declarative or procedural languages; and it can be deployed on a system of one or more computers in any form, including as a stand-alone program, e.g., as an app, or as a module, component, engine, subroutine, or other unit suitable for executing in a computing environment, which environment may include one or more computers interconnected by a data communication network in one or more locations.

A computer program may, but need not, correspond to a file in a file system. A computer program can be stored in a portion of a file that holds other programs or data, e.g., one or more scripts stored in a markup language document, in a single file dedicated to the program in question, or in multiple coordinated files, e.g., files that store one or more modules, sub-programs, or portions of code.

The processes and logic flows described in this specification can be performed by one or more computers executing one or more computer programs to perform operations by operating on input data and generating output. The processes and logic flows can also be performed by special-purpose logic circuitry, e.g., an FPGA, an ASIC, or a GPU, or by a combination of special-purpose logic circuitry and one or more programmed computers.

Computers suitable for the execution of a computer program can be based on general or special-purpose microprocessors or both, or any other kind of central processing unit. Generally, a central processing unit will receive instructions and data from a read-only memory or a random access memory or both. The essential elements of a computer are a central processing unit for executing instructions and one or more memory devices for storing instructions and data. The central processing unit and the memory can be supplemented by, or incorporated in, special-purpose logic circuitry.

Generally, a computer will also include, or be operatively coupled to, one or more mass storage devices, and be configured to receive data from or transfer data to the mass storage devices. The mass storage devices can be, for example, magnetic, magneto-optical, or optical disks, or solid state drives. However, a computer need not have such devices.

Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

To provide for interaction with a user, embodiments of the subject matter described in this specification can be implemented on one or more computers having, or configured to communicate with, a display device, e.g., a LCD (liquid crystal display) or organic light-emitting diode (OLED) monitor, a virtual-reality (VR) or augmented-reality (AR) display, for displaying information to the user, and an input device by which the user can provide input to the computer, e.g., a keyboard and a pointing device, e.g., a mouse, a trackball or touchpad. Other kinds of devices can be used to provide for interaction with a user as well; for example, feedback and responses provided to the user can be any form of sensory feedback, e.g., visual, auditory, speech or tactile; and input from the user can be received in any form, including acoustic, speech, or tactile input, including touch motion or gestures, or kinetic motion or gestures or orientation motion or gestures. In addition, a computer can interact with a user by sending documents to and receiving documents from a device that is used by the user; for example, by sending web pages to a web browser on a user's device in response to requests received from the web browser, or by interacting with an app running on a user device, e.g., a smartphone or electronic tablet. Also, a computer can interact with a user by sending text messages or other forms of message to a personal device, e.g., a smartphone that is running a messaging application, and receiving responsive messages from the user in return.

This specification uses the term “configured to” in connection with systems, apparatus, and computer program components. That a system of one or more computers is configured to perform particular operations or actions means that the system has installed on it software, firmware, hardware, or a combination of them that in operation cause the system to perform the operations or actions. That one or more computer programs is configured to perform particular operations or actions means that the one or more programs include instructions that, when executed by data processing apparatus, cause the apparatus to perform the operations or actions. That special-purpose logic circuitry is configured to perform particular operations or actions means that the circuitry has electronic logic that performs the operations or actions.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of what is being claimed, which is defined by the claims themselves, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

What is claimed is:

1. A computing system comprising:
one or more processors; and
one or more memories storing a site plan template, a set of pre-defined design elements corresponding to available cell site equipment, and instructions that, when executed by the one or more processors, configure the computing system to execute a site plan generator tool, the site plan generator tool to perform operations comprising:
receiving, from a user device, user input about a cell site of a cellular network, the user input comprising tower requirements, antenna requirements, and equipment requirements;
receiving, from the user device, a request to generate a cell site construction plan using the user input;
automatically in response to the request:
retrieving a copy of the site plan template to generate the cell site construction plan, the site plan template comprising a pre-defined layout of frames, each frame being assigned to include at least one of information or graphics, associated with the cell site equipment for the cell site, in a specific location in the cell site construction plan, wherein the cell site equipment comprises a tower or mounting structure, an antenna, a radio equipment, and a power system for the cell site;
identifying, using the user input, a subset of design elements from the set of pre-defined design elements, the subset of design elements comprising design elements corresponding to the tower or mounting structure, the antenna, the radio equipment, and the power system;
populating a plurality of frames of the cell site construction plan with the subset of design elements; and
sending the cell site construction plan to the user device.

2. The computing system of claim 1, wherein the site plan generator tool comprises an artificial intelligence or machine learning model (AI/ML model) trained to extract site information and an equipment schedule from the user input and identify the subset of design elements corresponding to the tower or mounting structure, the antenna, the radio equipment, and the power system that meet the tower requirements, the antenna requirements, and the equipment requirements.

3. The computing system of claim 1, wherein the site plan generator tool, to identify the subset of design elements, is further to perform operations comprising:
analyzing the user input to extract site information and an equipment schedule; and
generating, using the site information and the equipment schedule, one or more dynamic blocks, each dynamic block corresponding to one of the set of pre-defined design elements and comprising:
one or more modifiable parameters;
one or more actions that link to the one or more modifiable parameters that control behavior of the respective dynamic block;
visibility states that allows the respective dynamic block to display different configurations or appearances;
look-up tables (LUTs) that enable predefined sets of values for the one or more modifiable parameters to ensure consistent modifications when the one or more modifiable parameters change; and
one or more constraints that maintain geometric relationships within the respective dynamic block when the one or more modifiable parameters change, wherein the plurality of frames are populated with the one or more dynamic blocks.

4. The computing system of claim 3, wherein the one or more dynamic blocks comprises at least one of:
a first dynamic block corresponding to a plurality of types for the tower or mounting structures;
a second dynamic block corresponding to a plurality of types for the antenna;
a third dynamic block corresponding to a plurality of types for the radio equipment; or
a fourth dynamic block corresponding to a plurality of types of antenna mounts for the antenna.

5. The computing system of claim 3, wherein the site plan generator tool, to generate the one or more dynamic blocks, is to perform operations comprising:
identifying, using the user input, a first set of values from the predefined sets of values in the look-up tables of the respective dynamic block;
updating the one or more modifiable parameters with the first set of values using a block editor in a Computer-Aided Design (CAD) program with the one or more constraints that causes the CAD program to modify the corresponding pre-defined design element to an updated design element; and
updating the visibility state with the updated design element.

6. The computing system of claim 1, wherein the site plan generator tool is further to perform operations comprising:
automatically recognizing information from the user input to populate one or more title blocks of the cell site construction plan, wherein the one or more title blocks are assigned to specific locations in the cell site construction plan.

7. The computing system of claim 1, wherein:
the user input comprises one or more files comprising one or more of the following:
fiber design information including layout and specification of fiber-optic cables for the cell site;
power design information indicating how electrical power is distributed to the cell site;
a site candidate information package with potential locations for the cell site equipment;
geographic and topographic survey information of the cell site;
tower structural information about the tower or mounting structure;
antenna mount information to ensure mounting of the antenna on the tower or mounting structure;
legal description information defining a specific area of land granted for use by the cell site and access rights and restrictions on the specific area of land;
a radio frequency data sheet (RFDS) comprising radio frequency configurations, antenna parameters, and settings for a specified network performance; and
aerial imagery and data about the cell site;
a first frame of the plurality of frames is assigned a first equipment detail category, the first frame comprising a first label identifying the first equipment detail category and a first visibility state comprising a first equipment name of a first equipment, first equipment details of the first equipment, and one or more graphical views of the first equipment; and
a second frame of the plurality of frames is assigned a second equipment detail category, the second frame comprising a second label identifying the second equipment detail category and a second visibility state comprising a second equipment name of a second equipment, second equipment details of the second equipment, and one or more views of the second equipment.

8. The computing system of claim 1, wherein the antenna requirements comprises a radio frequency data sheet (RFDS), and wherein, to identify the subset of design elements, the site plan generator tool is further to perform operations comprising:
determining antenna dimensions and type of an antenna using the RFDS and the tower requirements; and
identifying a first pre-defined design element corresponding to the antenna type, and wherein populating the plurality of frames comprises populating a first frame with the first pre-defined design element having the antenna dimensions, wherein the first frame comprises a first label identifying an antenna category and a first visibility state comprising the antenna type, the antenna dimensions, and one or more views of the antenna.

9. The computing system of claim 1, wherein the user input comprises two or more of the following:
power design data;
fiber design data;
site data;
geological survey data;
mount analysis data;
structural analysis data;
legal description data;
radio frequency design specification data; and
image data of the cell site captured by a drone, wherein, to identify the subset of design elements, the site plan generator tool is further to perform operations comprising:
extracting a plurality of features from the user input; and
identifying the subset of design elements using an artificial intelligence or machine learning model (AI/ML model) and the plurality of features, wherein an output of the AI/ML model comprises the cell site construction plan.

10. The computing system of claim 1, wherein the site plan generator tool is further to perform operations comprising:
receiving, from the user device, additional user input to change i) one or more parameters of the cell site equipment or ii) a view of one or more of the subset of design elements in one or more frames of the pre-defined layout of frames, the one or more parameters comprises an equipment name, equipment details, or equipment dimensions associated with one or more of the subset of design elements; and
updating, using the additional user input, i) the one or more of the subset of design elements in the pre-defined layout of frames or ii) the view of the one or more of the subset of design elements in the one or more frames of the pre-defined layout of frames.

11. A method comprising:
storing a construction plan template for cell sites in a cellular network, the construction plan template comprising a pre-defined layout of frames, each frame being assigned to include at least one of information or graphics, associated with cell site equipment for the cell site, in a specific location in the construction plan template;
storing a set of pre-defined design elements corresponding to available cell site equipment, the available cell site equipment comprising a plurality of tower or mounting structures, a plurality of antennas, a plurality of radio equipment, and a plurality of power systems;
receiving, from a user device, user input about a cell site in the cellular network, the user input comprising tower requirements, antenna requirements, and equipment requirements;
receiving, from the user device, a request to generate a cell site construction plan using the user input and the construction plan template;
automatically in response to the request:
retrieving a copy of the construction plan template to generate the cell site construction plan;
identifying, using the user input, a subset of design elements from the set of pre-defined design elements, the subset of design elements comprising design elements corresponding to one of the plurality of tower or mounting structures, to one of the plurality of antennas, one of the plurality of radio equipment, and one of the plurality of power systems;
populating a plurality of frames of the cell site construction plan with the subset of design elements; and
sending the cell site construction plan to the user device.

12. The method of claim 11, wherein identifying the subset of design elements comprises identifying the subset of design elements using an artificial intelligence or machine learning model (AI/ML model) trained to extract site information and an equipment schedule from the user input and identify the subset of design elements corresponding to the tower or mounting structure, the antenna, the radio equipment, and the power system that meet the tower requirements, the antenna requirements, and the equipment requirements.

13. The method of claim 11, wherein identifying the subset of design elements comprises:
analyzing the user input to extract site information and an equipment schedule; and
generating, using the site information and the equipment schedule, one or more dynamic blocks, each dynamic block corresponding to one of the set of pre-defined design elements and comprising:
one or more modifiable parameters;
one or more actions that link to the one or more modifiable parameters that control behavior of the respective dynamic block;
visibility states that allows the respective dynamic block to display different configurations or appearances;
look-up tables (LUTs) that enable predefined sets of values for the one or more modifiable parameters to ensure consistent modifications when the one or more modifiable parameters change; and
one or more constraints that maintain geometric relationships within the respective dynamic block when the one or more modifiable parameters change, wherein the plurality of frames are populated with the one or more dynamic blocks.

14. The method of claim 11, wherein the antenna requirements comprises a radio frequency data sheet (RFDS), and wherein identifying the subset of design elements comprises:
determining antenna dimensions and type of an antenna using the RFDS and the tower requirements; and
identifying a first pre-defined design element corresponding to the antenna type, and wherein populating the plurality of frames comprises populating a first frame with the first pre-defined design element having the antenna dimensions, wherein the first frame comprises a first label identifying an antenna category and a first visibility state comprising the antenna type, the antenna dimensions, and one or more views of the antenna.

15. The method of claim 11, further comprising:
receiving, from the user device, additional user input to change i) one or more parameters of the cell site equipment or ii) a view of one or more of the subset of design elements in one or more frames of the pre-defined layout of frames, the one or more parameters comprises an equipment name, equipment details, or equipment dimensions associated with one or more of the subset of design elements; and
updating, using the additional user input, i) the one or more of the subset of design elements in the pre-defined layout of frames or ii) the view of the one or more of the subset of design elements in the one or more frames of the pre-defined layout of frames.

16. A method comprising:
receiving, from a user device, user input about a cell site of a cellular network, the user input comprising two or more of the following: power design data; fiber design data; site data; geological survey data; mount analysis data; structural analysis data; legal description data; radio frequency design specification data; and image data of the cell site captured by an aircraft or satellite;
extracting a plurality of features from the user input; and
identifying, using an artificial intelligence or machine learning model (AI/ML model) and the plurality of features, a subset of design elements from a set of pre-defined design elements for cell site equipment;
generating, using the subset of design elements, a cell site construction plan; and
sending the cell site construction plan to the user device.

17. The method of claim 16, wherein extracting the plurality of features comprises extracting site information and an equipment schedule from the user input, wherein the AI/ML model is trained to identify the subset of design elements corresponding to a tower or mounting structure, an antenna, a radio equipment, and a power system that meet tower requirements, antenna requirements, and equipment requirements.

18. The method of claim 16, wherein identifying the subset of design elements comprises:
analyzing the user input to extract site information and an equipment schedule; and
generating, using the site information and the equipment schedule, one or more dynamic blocks, each dynamic block corresponding to one of the set of pre-defined design elements and comprising:
one or more modifiable parameters;
one or more actions that link to the one or more modifiable parameters that control behavior of the respective dynamic block;
visibility states that allows the respective dynamic block to display different configurations or appearances;
look-up tables (LUTs) that enable predefined sets of values for the one or more modifiable parameters to ensure consistent modifications when the one or more modifiable parameters change; and
one or more constraints that maintain geometric relationships within the respective dynamic block when the one or more modifiable parameters change, wherein the plurality of frames are populated with the one or more dynamic blocks.

19. The method of claim 18, further comprising populating a plurality of frames of a site plan template with the subset of design elements to generate the cell site construction plan.

20. The method of claim 16, further comprising:
receiving, from the user device, additional user input to change i) one or more parameters of the cell site equipment or ii) a view of one or more of the subset of design elements in one or more frames of a pre-defined layout of frames, the one or more parameters comprises an equipment name, equipment details, or equipment dimensions associated with one or more of the subset of design elements; and
updating, using the additional user input, i) the one or more of the subset of design elements in the predefined layout of frames or ii) the view of the one or more of the subset of design elements in the one or more frames of the pre-defined layout of frames.
